(19) United States
(12) Patent Application Publication
(10) Pub. No.: US 2006/0051968 A1
(43) Pub. Date: Mar. 9, 2006

(54) Self-aligned contact etch with high sensitivity to nitride shoulder

(76) Inventors: Ajey M. Joshi, San Jose, CA (US); Pui Man Agnes Ng, Sunnyvale, CA (US); James A. Stinnett, Mountain View, CA (US); Usama Dadu, Hollister, CA (US); Jason M. Regis, Kingston, NH (US)

Correspondence Address: Patent Counsel;MS/2061, Legal Affairs Dept, P O Box 450A, Santa Clara, CA, 95052, US

(21) Appl. No.: 10/498,857

(22) PCT Filed: Dec. 12, 2002
(86) PCT No.: PCT/US02/39906

§ 371 Date: Jan. 6, 2005

Related U.S. Application Data
(60) Provisional application No. 60/341,135, filed on Dec. 13, 2001.

(51) Int. Cl. H01L 21/302; H01L 21/461

(52) U.S. Cl. 438/723; 438/712; 438/711; 438/710

(57) ABSTRACT

A method and apparatus are provided for etching semiconductor and dielectric substrates through the use of plasmas based on mixtures of a first gas having the formula CₐF_{b}, and a second gas having the formula CₓH_{y}F_{z}, wherein a/b≧⅔, and wherein x/z≧½. The mixtures may be used in low or medium density plasmas sustained in a magnetically enhanced reactive ion chamber to provide a process that exhibits excellent corner layer selectivity, photo resist selectivity, under layer selectivity, and profile and bottom CD control. The percentages of the first and second gas may be varied during etching to provide a plasma that etches undoped oxide films or to provide an etch stop on such films.

### FIELD OF THE INVENTION

This invention relates generally to plasma etching, and more particularly to plasma etching of dielectric materials using fluorochemicals.

### BACKGROUND OF THE INVENTION

Oxides and nitrides are used widely in the manufacture of microprocessors and other semiconductor devices. Oxides are particularly useful, due to the ability to readily change the conductive properties of these materials from a dielectric state to a semiconducting state through ion implantation or through other commonly used doping methodologies.

In many semiconductor manufacturing processes, the need arises to etch holes through one or more layers of doped or undoped oxide disposed in the proximity of a nitride layer. One example of this situation occurs during the manufacture of wafers equipped with Self-Aligned Contact (SAC) structures of the type depicted in FIG. 1. In such a construct, two gate structures 10 are formed on a silicon substrate 2 and are separated by a gap 12. The gate structures and the bottom of the gap are covered with a conformal layer of silicon nitride 14, which in turn is covered in a layer of field oxide 18.

At some point during the manufacturing process, the field oxide layer must be etched down to the nitride layer so that the portion 24 of the nitride layer at the bottom of the gap can be removed and electrical contact can be made with the n-type or p-type well 16 formed in the silicon substrate below. During this process, it is extremely important that the nitride layer over the gate structures is not significantly reduced in thickness, since doing so increases the likelihood of an electrical shortage in the completed device and can seriously degrade its performance.

Unfortunately, the nitride layer on the shoulder of the gate structure is highly prone to thinning or “faceting” during the etching process, both because of its geometry and because of the length of time it is exposed to the etching plasma during the etching process. It is thus important that the etching plasma be highly selective to the corner nitride. It is also important that the etching plasma be selective to the photoresist employed in the etching process so that a hole of the correct dimensions and geometry may be obtained. Moreover, it is very important that the etching process does not extend the hole being etched into the n-type or p-type well 16 positioned below the gap 16, since doing so would again adversely affect the performance of the device. Hence, it is also important that the etching process be capable of exhibiting etch stop behavior on doped oxide, and/or high selectivity to the flat nitride portion extending between the gate structures.

The use of a variety of fluorocarbons have been explored in etching situations, and in particular those involving SAC structures of the type depicted in FIG. 1, due in part to the high selectivity that fluorocarbons provide. Thus, in U.S. Pat. No. 6,174,451 (Hung et al.), etching of the substrate depicted in FIG. 1 is achieved through a two-step process. In the first step, C₄F₆/Ar is used in a main etch that removes the field oxide layer down to the conformal layer of silicon nitride. In the second step, C₄F₆/Ar/CH₂F₂ is used for an over etch, so called because the total oxide etching time is set significantly higher than that required to etch the design thickness of the oxide layer. The over etch is required to compensate for the fact that the substrate used in Hung et al. has a wavy surface, which in turn produces an oxide thickness that varies significantly. Hence, the over etch is required to assure penetration of the oxide layer. CH₂F₂/O₂/Ar is then used to etch the nitride layer prior to a subsequent metal implantation step. The main etch is said to provide a hole with a good vertical profile, while the over etch with the strongly polymerizing CH₂F₂ causes the deposition of a fluoropolymer over the corner nitride, thereby providing some protection against faceting. The reference advocates the use in the main etch of fluorocarbons having 3 or more carbon atoms and having an F/C ratio of at least 1 but less than 2.

While methodologies such as those disclosed in U.S. Pat. No. 6,174,451 (Hung et al.) represent notable advances in the art and are useful in a wide variety of situations, these methodologies were designed for larger feature sizes. Thus, the SACs used in Hung et al. had trench openings of about 0.35 microns. However, many semiconductor devices today are required to have trench openings of less than 0.25 microns, and sometimes even as small as 0.14 microns or less.

Unfortunately, the efficacy of methodologies of the type disclosed in Hung et al. are seen to decrease with decreasing features sizes. This is due in part to the fact that shrinking feature sizes dictate the use of thinner nitride layers, thus requiring even greater selectivity of the plasma to nitride, and especially to the corner nitride. Thus, for example, a device having a gap of 0.25 microns will have a nitride layer which is about 500 to 700 Å thick, or about 100 to 200 Å thinner than a comparable device having a gap of 0.35 microns. Unfortunately, the chemistries used in the main etch of Hung et al. (most notably C₄F₆/Ar) provide insufficient selectivity for the thinner nitride layers required by devices having feature sizes less than about 0.25 microns, with the result that an unacceptable amount of faceting is found to occur in the corner nitride. Moreover, while it might be theoretically possible to time the main etch of the field oxide layer so that it terminates before the corner nitride is reached, in practice this is difficult to accomplish due to the fact that the timing can be affected by a large number of process variabilities and can therefore vary considerably from one etch to another.

Moreover, in many applications involving small feature sizes, it is necessary to etch an oxide layer which is disposed over active regions of doped silicon that have been formed through ion implantation methods or by other processes. These active regions will frequently have thicknesses that are substantially less than the depth of the etched hole (the oxide thickness). However, chemistries such as C₄F₆/Ar are non-selective to doped and undoped oxides (that is, they etch both doped and undoped oxide at a similar rate). Due to the timing issues noted above, it is difficult to etch a substrate such as that depicted in FIG. 1 through the use of a non-selective oxide etch and, in doing so, to control the timing of the etch so that it will etch through most or all of the silicon oxide without a substantial probability of also etching through the flat portion of the conformal nitride layer and into the underlying active silicon region of the p-type or n-type well.

The use of certain Freon 134 chemistries such as C₂H₂F₄/CHF₃/Ar have also been explored in etching processes. These chemistries are desirable in that they promote the formation of a protective fluoropolymer layer on the sides of a hole to be etched, and hence afford some protection to the corner nitride against faceting. However, while these chemistries have many desirable characteristics, the formulations and methodologies explored to date cannot be used to etch feature sizes smaller than about 0.18 microns without resulting in excessive polymer deposition, which leads to occlusion of the feature hole and an incomplete etch.

There is thus a need in the art for an etching chemistry that is highly selective to both photo resist and nitride (including both flat nitride and corner nitride), which does not entail excessive polymer deposition, and which is suitable for use in devices having small feature sizes (e.g., less than about 0.18 microns). These and other needs are met by the present invention, as hereinafter described.

### SUMMARY OF THE INVENTION

In one aspect, the present invention relates to a method for etching a substrate, such as a semiconducting or dielectric substrate, using a plasma based on a mixture of O₂ and at least a first gas having the formula CₐF_{b} and a second gas having the formula CₓH_{y}F_{z}. The chemical composition of these gases are such that typically at least one, more typically at least two, and most typically all three of the following conditions are satisfied:
a/b≧⅔
x/z≧½; and
x/y≧⅓.
The dissociation of CₓH_{y}F_{z} is found to result in unique polymers that adhere well to the sidewalls of the hole being etched, thereby resulting in high selectivity to the corner nitride. Moreover, with the inclusion of O₂ in the gas mixture, the resulting plasma may be utilized to etch advanced structures having small feature sizes (e.g., less than about 0.25 microns) without any substantial occlusion of the hole. Thus, for example, the methodology is well suited to etching SAC structures having gaps between the gate structures of less than about 0.25 microns, less than about 0.18 microns, and indeed even less than about 0.14 microns.

In another aspect, the present invention relates to a method for etching a substrate which contains an undoped oxide layer and a doped oxide layer. The substrate may include, for example, an SAC structure having a gap between the gate structures of less than about 0.25 microns, having a conformal layer of nitride overlying the gate structures, and having a layer of undoped oxide and doped oxide disposed over the conformal layer, with the layer of doped oxide disposed between the layer of undoped oxide and the conformal nitride layer. The undoped oxide layer is then etched using a plasma based on a gas stream which includes a first gas having the formula CₐF_{b} until the doped oxide layer is reached. The point at which the doped oxide is reached may be determined, for example, by spectrographic analysis geared toward detecting the presence of the dopant, or by other suitable means. Next, the doped layer is etched using a plasma based on a gas stream which includes a second gas having the formula CₓH_{y}F_{z}. The chemical composition of these gases are such that typically at least one, more typically at least two, and most typically all three of the following conditions are satisfied:
a/b≧⅔
x/z≧½; and
x/y≧⅓.
Since, as noted above, CₓH_{y}F_{z} causes the deposition of novel fluoropolymers on the side walls of the hole that protect the underlying nitride from being etched, these gases exhibit better corner nitride selectivity than CₐF_{b}. On the other hand, the use of CₐF_{b} in the main etch is advantageous in that it produces a hole with a better vertical profile than could be achieved with CₓH_{y}F_{z} alone. Moreover, CₐF_{b} is a nonselective oxide etch, while certain mixtures of CₓH_{y}F_{z} (such as C₂H₂F₄ with CHF₃ and Ar) exhibit etch stop behavior on undoped oxide. Typically, the first gas is C₄F₆ and the second gas is C₂H₂F₄.

In another aspect, the present invention relates to a method for etching a substrate, such as a semiconducting or dielectric substrate, using a plasma based on a mixture of C₄F₆ and C₂H₂F₄. The mixture typically further contains O₂, and also typically contains Ar or another inert gas as a carrier.

In another aspect, the present invention relates to a method for etching a substrate, such as a semiconducting or dielectric substrate, comprising the steps of first etching the substrate with a plasma based on C₄F₆, and then etching the substrate with a plasma based on C₂H₂F₄.

In still another aspect, the present invention relates to a method for etching a substrate, comprising the steps of (a) positioning in a chamber a structure comprising a first layer disposed on a substrate, the first layer being selected from the group consisting of dielectric layers and semiconductor layers; (b) supplying a reactive gas mixture to the chamber, the gas mixture comprising a first gas having the formula CₐF_{b} and a second gas having the formula CₓH_{y}F_{z}, wherein a/b≧⅔ and x/z≧½; (c) applying sufficient RF energy to the chamber to establish an etching plasma and an associated electric field perpendicular to the surface of the substrate; (d) applying a magnetic field to the chamber substantially perpendicular to the electric field and substantially parallel to the surface of the substrate; and (e) allowing the plasma to etch at least a portion of the first layer.

In yet another aspect, the present invention relates to a method for etching a substrate, comprising the steps of (a) providing a substrate selected from the group consisting of semiconductor and dielectric substrates; and (b) etching the substrate through a magnetically enhanced reactive ion etch process, the process including the addition of a source of hydrogen radicals to a gas mixture in an amount sufficient to increase the value of at least one parameter selected from the group consisting of etch rate and selectivity of the reactive gas mixture for the substrate. The gas mixture comprises a first gas having the formula CₐF_{b} and a second gas having the formula CₓH_{y}F_{z}, wherein a/b≧⅔ and x/z≧½.

In still another aspect, the present invention relates to an apparatus for etching substrates, comprising a chamber adapted to receive a substrate to be etched and at least one reservoir in open communication with the chamber. The at least one reservoir is adapted to supply a gas mixture to the chamber comprising a first gas having the formula CₐF_{b} and a second gas having the formula CₓH_{y}F_{z}, wherein a/b≧⅔ and x/z≧½. The gas mixture typically also comprises oxygen.

In another aspect, the present invention relates to a method for etching a substrate, comprising the steps of (a) providing a substrate selected from the group consisting of semiconductor and dielectric substrates; (b) etching the substrate through the use of a plasma based on a gaseous mixture of at least C₄F₆, O₂, and Ar, thereby forming a modified substrate; and (c) further etching the modified substrate through the use of a plasma based on a gaseous mixture of at least C₄F₆, O₂, Ar, and C₂H₂F₄.

In still another aspect, the present invention relates to a method for etching a substrate, comprising the steps of (a) providing a substrate comprising (i) a first layer, (ii) a second layer comprising a doped oxide such as boron phosphorosilicate glass, (iii) a fourth layer comprising an antireflective material, and (iv) a third layer, disposed between the second and fourth layer, comprising an undoped oxide such as tetraethylorthosilicate; (b) etching the substrate through the use of a plasma based on a first gaseous mixture comprising C₄F₆, O₂ and Ar so as to form a depression that extends through the fourth layer and at least partially through the third layer, but does not extend substantially into the second layer; and (c) further etching the substrate through the use of a plasma based on a second gaseous mixture comprising C₄F₆, O₂, C₂H₂F₄, and Ar so as to extend the depression substantially into the second layer.

In yet another aspect, the present invention relates to a method for controlling profile and/or Mean Wafer Between Wet Clean (MWBWC) performance in a plasma etching process. In accordance with the method, a gas mixture comprising CₓH_{y}F_{z}/CₐF_{b}/O₂ is used in the etching process. The CₓH_{y}F_{z}/CₐF_{b}/O₂ ratio is manipulated to control the degree of polymerization, which in turn controls the profile and Mean Wafer Between Wet Clean (MWBWC) performance.

In yet another aspect, the present invention relates to a substrate equipped with an SAC structure comprising first and second gate structures disposed on a silicon substrate. The gate structures have a gap between them of less than about 0.25 microns, typically less than about 0.18 microns, and most typically less than about 0.14 microns, and are covered by a layer of silicon nitride. A layer of undoped oxide is disposed over the layer of silicon nitride, and a layer of doped silicon oxide is disposed between the layer of undoped oxide and the layer of silicon nitride. Typically, the layer of doped oxide is thick enough to cover the SAC structure. The structure may be advantageously employed in plasma etching operations based on gas mixtures comprising C₄F₆ and C₂H₂F₄ (which mixtures may further include O₂ and/or Ar) or in plasma etching operations involving etching with a first gas stream comprising C₄F₆ and a second gas stream comprising C₂H₂F₄ (these first and second gas streams may also further comprise O₂ and/or Ar) in that spectrographic methods may be used to determine completion of etching through the undoped oxide layer by detecting an increase in the concentration of dopant from the doped oxide layer in the etching chamber atmosphere. In this way, etching can be controlled reliably even with variations in processing parameters, and faceting of the nitride layer can be avoided.

### BRIEF DESCRIPTION OF THE DRAWINGS

FIG. 1 is a schematic drawing of a prior art SAC structure;

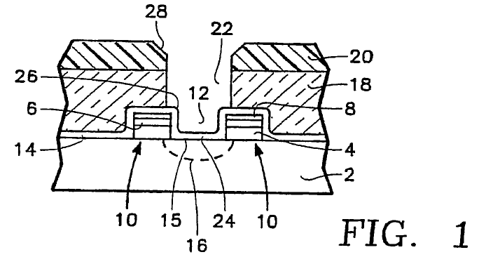

FIG. 2 is a schematic drawing of an exemplary etching chamber that may be used in connection with various embodiments of the invention; and

FIG. 3 is a schematic drawing of an SAC structure which may be etched using the methodology of the present invention.

### DETAILED DESCRIPTION OF PREFERRED EMBODIMENTS OF THE INVENTION

As a preface to the detailed description, it should be noted that, as used in this specification and the appended claims, the singular forms “a”, “an”, and “the” include plural referents, unless the context clearly dictates otherwise.

All percentages (%) listed for gas constituents are % by volume, and all ratios listed for gas constituents are volume ratios.

As used herein ,the term “selectivity” is used to refer to a) a ratio of etch rates of two or more materials and b) a condition achieved during etch when etch rate of one material is substantially different from another material.

As used herein, the term “oxide” generally refers to silicon dioxide and to other silicon oxides of the general formula SiOₓ, as well as to closely related materials such as borophosphosilicate (BPSG) and other oxide glasses.

As used herein, the term “nitride” refers to silicon nitride (Si₃N₄) and to its stoichiometric variants, the later being generally encompassed by the formula SiNₓ, where x is between 1 and 1.5.

The present invention now will be described more fully hereinafter with reference to the accompanying drawings, in which preferred embodiments of the invention are shown. This invention may, however, be embodied in different forms and should not be construed as limited to the embodiments set forth herein.

The present invention utilizes gas streams containing particular fluorocarbon gases to generate plasmas that are suitable for etching substrates. The substrates to be etched will typically comprise oxides, nitrides, and/or other semiconducting or dielectric materials of the type employed in the fabrication of semiconductor devices.

Various gases may be used in the gas streams of the present invention. The particular choice of gases to be used in the gas stream will depend on such factors as the particular substrate or material being etched, the required selectivity of the gas to one or more materials of interest such as a nitride layer or photoresist, the particular point in the etching process, and other such factors. Moreover, the composition of the gas stream may be varied as a function of time or as a function of the progress of the etching operation.

However, the preferred gases for use in the present invention are defined by the general formulas CₐF_{b} and CₓH_{y}F_{z}. Typically, the gas streams utilized will comprise mixtures of a first gas having the formula CₐF_{b} and a second gas having the formula CₓH_{y}F_{z}, although in some embodiments the first and second gases may instead be employed separately in independent processing steps. Thus, for example, the first gas may be employed in a first etching step (e.g., in a main etch), and the second gas may be employed in a second etching step (e.g., in an over etch). The chemical composition of these gases are such that typically at least one, more typically at least two, and most typically all three of the following conditions are satisfied:
a/b≧⅔;
x/z≧½; and
x/y≧⅓.
In the preferred embodiment, the first gas is C₄F₆ and the second gas is C₂H₂F₄ (Freon 134). In some situations, however, it may be desirable to substitute Freon 134 with CH₃F (x/y=⅓), CH₂F₂ (x/y=½), and/or trifluoromethane (CHF₃, x/y=1). It may also be desirable in some situations to replace C₄F₆ with octafluorocyclobutane (C₄F₈).

The gas streams used in the present invention will also typically comprise an inert carrier gas. Argon is the preferred carrier gas, in part because it is inexpensive and is readily available from various commercial sources. However, other inert gases, such as nitrogen, helium or zenon, could also be used in this capacity.

The gas streams used in the present invention also typically comprise O₂. The addition of O₂ to the gas streams of the present invention is found to provide a number of advantages. In particular, many gases, such as C₂H₂F₄, cannot be used to etch SAC structures having a gap between the gate structures of less than 0.18 microns, because an excessive amount of polymerization occurs under typical etching conditions that leads to occlusion of the hole being etched. By contrast, gas streams containing O₂ and C₄F₆ can be used to etch such structures without substantial occlusion of the hole. Indeed, the use of C₄F₆/O₂ has been successfully used to etch feature sizes of less than about 0.14 microns. In some situations, similar results may be obtained by substituting ozone or certain partially fluorinated or perfluorinated ethers for O₂.

In some embodiments, the gas stream may also contain CO. The use of CO is advantageous in that it can be used in some instances to increase the carbon concentration of the plasma so that a high degree of polymerization can be achieved. This can be important, for example, when extremely high photo resist selectivity is required. Other additives as are known to the art may also be added to the gas stream for various purposes.

Plasmas can be generated from the gas streams of the present invention which contain optimized fluorocarbon radicals CFₙ (n=1, 2, 3) having desirable carbon concentrations. Through suitable manipulation of processing parameters, such as CₐF_{b}/CₓH_{y}F_{z} and CₐF_{b}/O₂ gas ratios, the total gas flow, additive gas flow, RF power, chamber pressure, and B-field intensity, a desirable degree of polymerization can be induced on the surfaces of the substrate being etched. The high carbon concentration polymers so formed provide excellent performance in a wide range of dielectric etch applications, and help improve corner and flat nitride selectivity, photo resist selectivity, under layer selectivity, and bottom critical dimension uniformity.

Moreover, by adjusting the CₓH_{y}F_{z}/CₐF_{b}/O₂ ratio in the gas stream and therefore the resulting degree of polymerization, better profile control and Mean Wafer Between Wet Clean (MWBWC) performance can be achieved. In addition, the resulting plasma contains less free F, which in turn makes the etch process less sensitive to the film being etched. Therefore, less tuning is required between doped and undoped dielectric films.

Mixtures of the first and second gas defined above are especially suitable for use in the present invention and afford a number of advantages. Thus, for example, plasmas based on CₓH_{y}F_{z} gases are often found to be selective to undoped oxide films. However, the addition of sufficient amounts of CₐF_{b} to the process gas mixture allows the resulting plasma to etch undoped oxide films to the desired depth without any etch stop. Conversely, the proportion of CₐF_{b} in the mixture can also be used as a processing knob when it is desired to etch stop on an undoped oxide layer. In particular, the amount of CₐF_{b} in the gas mixture can be reduced (to zero, if necessary) as the undoped oxide layer is approached to stop etching. Spectroscopic techniques or other suitable methods can be employed to detect the approach of doped or undoped oxide layers, typically by monitoring the chamber atmosphere for increases or decreases in dopant concentration.

Gas mixtures can also be made in accordance with the present invention which provide high nitride selectivity, particularly when these mixtures include oxygen. Thus, for example, C₄F₆/O₂/Ar/C₂H₂F₄ chemistry is found to provide good passivation on both sidewall nitride and flat nitride in SAC applications. By contrast, C₄F₆/O₂/Ar only chemistry does not exhibit as high of a corner nitride selectivity, although it gives good flat nitride selectivity.

Etching in accordance with the present invention is typically performed through the use of plasmas that are sustained in a low pressure chamber in which the substrate to be etched is mounted. The etching devices suitable for use in the present invention are not particularly limited. Rather, the methodology of the present invention can be practiced using a number of known plasma reactors. Such reactors include, for example, the IPS etch reactor, which is available commercially from Applied Materials and which is described in U.S. Pat. No. 6,238,588 (Collins et al.) and in European Patent Publication EP-840,365-A2, as well as the reactors described in U.S. Pat. No. 6,705,081 and in U.S. Pat. No. 6,174,451 (Hung et al.).

Typically, however, the methodology of the present invention is practiced through the use of a low or medium density plasma sustained in a Magnetically Enhanced Reactive Ion Etch (MERIE) chamber. The etching chamber is in communication with reservoirs of the gases used to generate the plasma. These reservoirs may comprise, for example, cylinders of Ar, O₂, CO, NH₃, CₓH_{y}F_{z}, and CₐF_{b}.

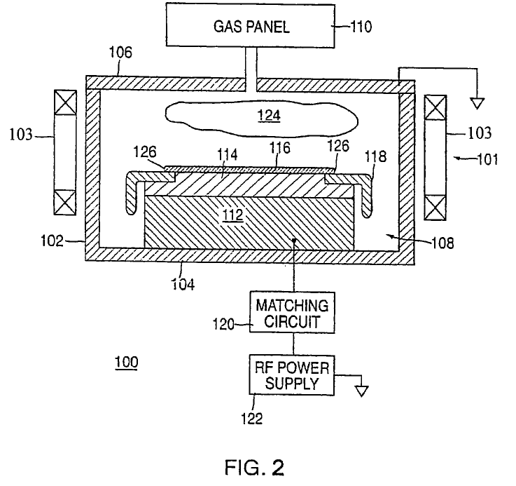

FIG. 2 is a simplified schematic diagram of a MERIE system 100 suitable for use in the present invention. The system 100 includes a processing chamber 101. The chamber 101 comprises a set of side-walls 102, a floor 104 and a lid 106, defining an enclosed volume. A gas panel 110 supplies reactive gases (an etch chemistry) to the enclosed volume defined by the chamber 101. The system 100 further includes an RF power supply 122 and a matching circuit 120 that drives a pedestal assembly 108 such that an electric field is established between the pedestal assembly 108 and the chamber walls 102 and lid 106. A set of coils 124 are arranged about the sides 102 of the chamber 101 to facilitate magnetic control of the plasma 124.

A pedestal assembly 108 comprises a pedestal 114 centrally mounted within the chamber 101 to a cathode 112 and surrounded by a collar 118. The pedestal retains a workpiece 116 such as a semiconductor wafer which is to be processed in the chamber 101. The plasma reaction chamber 101 employs capacitively coupled RF power to generate and maintain a low energy plasma 124. The plasma may be low, medium, or high density, although low to medium density plasmas are preferred in the practice of the present invention. RF power is coupled from the RF power supply 122 producing one or more RF frequencies through matching network 120. The lid 106 and walls 102 are grounded and serve as a ground reference (anode) for the RF power. With the configuration shown in FIG. 2, plasma density is controlled by the RF power provided by the power supply 122 via the matching circuit 120.

In semiconductor wafer processing, the cathode 112 is typically fabricated from a conductive material such as aluminum. The pedestal 114 is typically fabricated from a polymer such as polyimide or a ceramic material such as aluminum nitride or boron nitride. The workpiece 116 (i.e., a semiconductor wafer) is typically made of silicon. The electric field that couples to the plasma passes through both the workpiece and the pedestal. Since the cathode and workpiece are made of diverse materials, these materials have different effects on the plasma. Consequently, there is an abrupt change of plasma parameters, and process uniformity, at the wafer edge 126. To improve process uniformity at the wafer edge, a collar 118 surrounds and partially overlaps the pedestal 114. The collar 118 (also known as a process kit) is typically made of a material such as quartz.

In use, a gas stream is supplied through the gas panel 110 from one or more gas sources. Typically, these sources will be pressurized tanks containing the various components of the desired etch chemistry, such as Ar, O₂, C₄F₆; and C₂H₂F₄, which are connected to the gas panel by one or more gas feeds. The gas sources will typically be under the control, either directly or indirectly, of a system controller in which is stored the process recipe in magnetic or semiconductor memory, so that the flow of gas from these sources can be independently regulated to control or modify the compositional makeup of the atmosphere in the chamber. A vacuum pumping system may be connected to the chamber to maintain the chamber at a preselected pressure.

A variety of accessories and improvements to MERIE chambers and technologies have been developed which can be used advantageously in the practice of the present invention. For example, U.S. Pat. No. 6,232,236 (Shan et al.) describes methods for improving the control of plasma uniformity as well as ion energy and radical component uniformity across the wafer surface in a MERIE chamber so as to provide for more uniform and repeatable etching of wafers. These methods, and the improved MERIE chambers described in Shan et al., can also be applied in the practice of the present invention.

Optical Emission Spectroscopy (OES) can be used advantageously in the present invention as a monitoring process for end-point detection in plasma etching. In a chamber of the type depicted in FIG. 2, this may facilitated, for example, by the provision of an optical fiber which is placed in a hole penetrating the chamber wall to laterally view the plasma area above the wafer. An optical detector system may be connected to the other end of the fiber and may include one or more optical filters and processing circuitry that are tuned to the plasma emission spectrum associated with one or more species in the plasma. Either the raw detected signals or a trigger signal is electronically supplied to the system controller, which can use the signals to determine that one step of the etch process has been completed as either a new signal appears or an old one decreases. With this determination, the system controller can adjust the process recipe or end the etching step.

In some applications of the present invention, the substrate to be etched can be designed to take advantage of this ability to determine the endpoint. For example, in advanced structures having small feature sizes, such as SAC structures having a gap between the gate structures of less than about 0.25 microns, corner nitride selectivity is very important. This is due in part to the fact that such smaller feature sizes require the conformal nitride layer disposed over the gate structures to be reduced in thickness (typically to within the range of 500 to 700 angstroms). Since corner nitride is typically prone to faceting anyway, it becomes necessary to compensate for this tendency by further increasing the corner nitride selectivity of the plasma.

In the context of the present invention, this can be accomplished by depositing an undoped layer of oxide and a doped layer of oxide over the SAC structure, with the doped layer disposed between the undoped layer and the conformal nitride layer. The undoped oxide may then be etched in a main etch using a chemistry such as C₄F₆ which provides a good vertical profile. OES can then be used to detect the emergence in the etching chamber atmosphere of the dopant from the doped oxide layer (this will typically be a material such as boron), which marks the endpoint of the main etch. The etching chemistry may then be changed to C₂H₂F₄ or another material exhibiting heightened corner nitride selectivity. The change in chemistry may be characterized by the complete replacement of C₄F₆ with C₂H₂F₄ when the endpoint is reached, or simply by an increase in the concentration of C₂H₂F₄ in the gas stream accompanied by a decrease in the concentration of C₄F₆. Through the use of this two-step process, the main etch may be readily controlled and stopped when the depth of the hole is in the proximity of the nitride layer, thereby avoiding faceting of the nitride layer.

The use of an undoped layer of oxide here in conjunction with the use of C₄F₆ as the main etchant is advantageous in that C₄F₆ provides a good vertical profile without occlusion of the hole. By contrast, the use of C₂H₂F₄ chemistry alone can, in some applications, lead to necking, and eventually hole occlusion, at the top of the hole as a result of polymerization. However, one skilled in the art will appreciate that, in applications where a shallower hole (e.g., less than about 3000 to 4000 Å) is desired and hence where the possibility of occlusion is minimal and the need for a good vertical profile is less critical, the entire oxide layer could be doped, and C₂H₂F₄ chemistry could be used in a single etching step to define the hole.

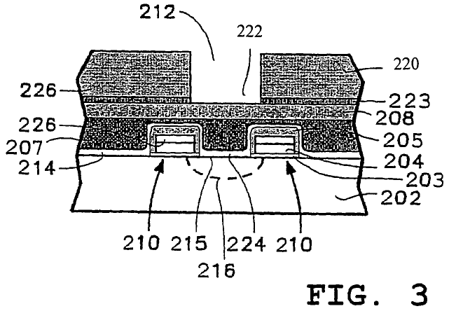

The methodologies of the present invention allow for the production of several types of advanced structures. An example of such an advanced structure is the self-aligned contact (SAC) structure for two transistors which is illustrated in the cross-sectional view of FIG. 3. The SAC structure is disposed on a silicon substrate 202 which may be, for example, silicon oxide or silicon nitride. The SAC structure is formed by depositing layers of a gate oxide 203, a polysilicon layer 204 (which may be doped or undoped) and an oxide hard mask 205, and photolithographically forming these layers into two closely spaced gate structures 210 having a gap 212 between them.

Chemical vapor deposition is then used to deposit onto the wafer a substantially conformal layer 214 of silicon nitride (Si₃N₄) about 100 to 500Å in thickness, which coats the top and sides of the gate structures 210 as well as the bottom 215 of the gap 212. The nitride acts as an electrical insulator. Dopant ions are ion implanted using the gate structures 210 as a mask to form a self-aligned p-type or n-type well 216, which acts as a common source for the two transistors having respective gates 210. The drain structures of the transistors are not illustrated.

An oxide layer is deposited over this previously defined structure. The oxide layer typically has a thickness of about 9000 Å in thickness and may be a single field oxide layer or, as depicted in FIG. 3, may have a two-part construction in which the first 5000 Å in thickness 7 has the structure TEOS/PET cos/PSG (with BPSG/PSG filling the gap between the gates) and the next 4000 Å is an undoped oxide 208 layer.

A photoresist layer 220 of between about 4000 Å and about 9000 Å is deposited over the oxide layer 218 and is photographically defined into a mask so that a subsequent oxide etching step etches a contact hole 222 through the oxide layer 218 and stops on the portion 224 of the nitride layer 214 underlying the hole 222. A post-etch sputter may be used to remove the nitride portion 224 at the bottom 215 of the gap 212. The silicon nitride acts as an electrical insulator for the metal, usually aluminum, thereafter filled into the contact hole 222. In some embodiments, a Birefringent Antireflective Coating (BARC) 223 or other type of material capable of eliminating the adverse effect of standing waves may optionally be applied. This material, which will typically be less than about 900 Å thick, will typically be provided between the oxide layer and the photoresist mask.

Several variations to the structure depicted in FIG. 2 are possible. Thus, in other specific embodiments, the hardmask is replaced with one of the following three sequences of layers:
(1) a layer of silicon nitride;
(2) a layer of tungsten silicide (WSiₓ), a layer of silicon nitride, and an oxide hardmask (in that order); or
(3) a layer of tungsten silicide (WSiₓ) and a layer of silicon nitride (in that order).

The significance of the selectivity offered by the gas mixtures of the present invention may be understood by considering the advantages afforded by SAC and other advanced structures, as well as the challenges these structures pose. Since nitride acts as an insulator, the SAC structure and process offer the advantage that the contact hole 222, which is typically about 0.14 to about 0.25 μm in diameter, may be wider than the width of the gap 212 between the gate structures 210. Additionally, the photolithographic registry of the contact hole 222 with the gate structures 210 need not be precise. However, to achieve these beneficial effects, the SAC oxide etch must be highly selective to nitride. Numerical values of selectivity are calculated as the ratio of the oxide to nitride etch rates. Selectivity is especially critical at the corners 226 of the nitride layer 214 above and next to the gap 212 since the corners 226 are the portion of the nitride exposed the longest to the oxide etch. Furthermore, they have a geometry favorable to fast etching that tends to create facets at the corners 226.

Furthermore, increased selectivity is being required with the increased usage of chemical mechanical polishing (CMP) for planarization of an oxide layer over a curly wafer. The planarization produces a flat oxide surface over a wavy underlayer substrate, thereby producing an oxide layer of significantly varying thickness. As a result, the time of the oxide etch must be set significantly higher, say by 100%, than the etch of the design thickness to assure penetration of the oxide. This is called over etch, which also accounts for other process variations. However, for the regions with a thinner oxide, the nitride is exposed that much longer to the etching environment.

Ultimately, the required degree of selectivity is reflected in the probability of an electrical short between the gate structures 210 and the metal filled into the contact hole 222. The etch must also be selective to photoresist, although photoresist selectivity is not as critical as nitride selectivity here since the photoresist layer 220 may be made much thicker than the nitride layer 214.

The invention will now be illustrated in reference to the following non-limiting examples:

### EXAMPLE 1

This experiment demonstrates the etch stop behavior of Freon 134 on undoped oxide.

A wafer was provided which consisted of a surface layer of 9% PSG at the center of the wafer disposed on an undoped oxide substrate. Three separate holes were etched into the wafer using a MERIE reactor equipped with an eMAX chamber and using a gas stream consisting of C₄F₆Freon 134/O₂/Ar. The processing parameters were as follows:

| | |
|---|---|
| Chamber Pressure: | 40 to 80 mTorr |
| Power used to generate plasma: | 1000 to 1800 watts |
| Cathode Temperature: | 15 to 35° C. |
| B-Field: | 0 to 50 Gauss |
| O₂ flow rate: | 15 sccm |
| Freon 134: | 2-8 sccm |
| Argon flow rate: | 500 sccm |
| C₄F₆ flow rate: | 20-30 sccm |

The duration of the etch was approximately 60 to 90 seconds. The plasma readily penetrated the doped oxide surface layer, but exhibited etch stop behavior with respect to the underlying substrate.

### EXAMPLE 2

This example illustrates the lack of selectivity Freon 134 exhibits with respect to flat nitride.

A wafer was provided which consisted of the following layer sequence:

| Material | Thickness |
|---|---|
| DUV PR | |
| BARC | 700 Å |
| TEOS | 4000 Å |
| BPSG | 4000 Å |
| SiON Liner | 180 Å |
| Polygate | |

Using the methodology and apparatus of EXAMPLE 1, the undoped oxide layer 8 was etched using C₄F₆/O₂/Ar chemistry at respective flow rate ratios of 25:15:500 until the BPSG layer was exposed.

Next, the chemistry was switched to Freon 134/CHF₃/Ar at respective flow rate ratios of 6:80:90, and etching was continued. The plasma penetrated the flat nitride layer at the bottom of the gap, thus demonstrating lack of selectivity of Freon 134 to flat nitride.

### EXAMPLE 3

This example illustrates the poor corner nitride selectivity exhibited by C₄F₆/O₂/Ar only chemistry.

The experiment of EXAMPLE 2 was repeated, using different chemistry. C₄F₆/O₂/Ar was used to etch through the TEOS layer with flow rates of 30/20/500, respectively. The etch was terminated after the plasma had penetrated the BPSG layer and had come into contact with the corner nitride. Next, C₄F₆/O₂/Ar/Freon 134A was used to etch through the BPSG layer using flow rates of 27/15/500/9, respectively. The plasma exhibited etch stop behavior with respect to the flat nitride portion, thus demonstrating the selectivity of C₄F₆/O₂/Ar/Freon 134A chemistry to flat nitride. However, the corner nitride was noticeably eroded where it had come into contact with the plasma during the first etching step, thus demonstrating that C₄F₆/O₂/Ar only chemistry exhibits poor corner nitride selectivity.

### EXAMPLE 4

This example illustrates the good corner nitride and flat nitride selectivity exhibited by Freon 134/C₄F₆/O₂/Ar chemistry.

The experiment of EXAMPLE 3 was repeated, except that the first etching step was terminated before the plasma came into contact with the corner nitride. C₄F₆/O_{2/}Ar/Freon 134A was used in the second etching step to etch through the BPSG layer using flow rates of 27/15/500/4, respectively.

The plasma again exlubited etch stop behavior with respect to flat nitride. In addition, however, corner nitride selectivity was noticeably improved, thus demonstrating the selectivity of C₄F₆/O₂/Ar/Freon 134A to corner nitride. The lower flow rate of Freon 134A here also demonstrates that Freon 134A is an effective polymer-forming agent even at low concentrations.

### EXAMPLE 5

This example illustrates the etch stop behavior of Freon 134/C₄F₆/O₂/Ar chemistry on undoped oxide.

The experiment of EXAMPLE 1 was repeated, except that C₄F₆/O₂/Ar/Freon 134 was used as the process gas at flow rates of 27/15/500/8, respectively. The resulting plasma was observed to exhibit good etch stop behavior on the undoped oxide layer. Typically, etch stop behavior is observed at flow rate ratios of Freon 134 of 8 or greater. Since excessive polymerization can occur if the flow rate ratio of Freon 134 is too high, flow rate ratios of Freon 134 within the range of about 8 to about 12 are typically used.

The above examples illustrate the ability, by changing the composition of the process gas, to etch both doped and undoped oxide, or to achieve etch stop on undoped oxide. The examples also illustrate the improvement in corner nitride selectivity achievable with mixtures of Freon 134 and C₄F₆, as compared to the results achieved with either gas alone.

Although the present invention has been described with respect to several exemplary embodiments, there are many other variations of the above-described embodiments that will be apparent to those skilled in the art. It is understood that these variations are within the teachings of the present invention, which is to be limited only by the claims appended hereto.

For example, all of the features disclosed in this specification (including any accompanying claims, abstract and drawings), and/or all of the steps of any method or process so disclosed, may be combined in any combination, except for combinations where at least some of the features and/or steps are mutually exclusive.

Moreover, each feature disclosed in this specification (including any accompanying claims, abstract, and drawings), may be replaced by alternative features serving the same equivalent or similar purpose, unless expressly stated otherwise. Thus, unless expressly stated otherwise, each feature disclosed is one example only of a generic series of equivalent or similar features.

1. A method for etching a substrate, comprising the steps of:
providing a substrate comprising at least one oxide layer, and
etching the oxide layer with a plasma based on a mixture of oxygen and at least a first and second gas;
wherein the first gas has the formula CₐF_{b}, wherein the second gas has the formula CₓH_{y}F_{z} wherein a/b≧⅔, wherein x/z≧½, and wherein a, b, x, y, and z are all greater than 0.

2. The method of claim 1, wherein x/y≧⅓.

3. The method of claim 1, wherein the mixture further comprises argon.

4. The method of claim 1, wherein a is 4.

5. The method of claim 1, wherein x is within the range of 1 to 3.

6. The method of claim 1, wherein the plasma has a density of less than about 1×10¹¹/cm³.

7. The method of claim 1, wherein the plasma has a density within the range of about 1×10⁹/cm³ to about 1×10¹¹/cm³.

8. The method of claim 1, wherein the substrate further comprises a layer of photo resist, and wherein the plasma has a photo resist selectivity of at least 6:1.

9. The method of claim 1, wherein the substrate further comprises a layer of photo resist, and wherein the plasma has a photo resist selectivity of at least 8:1.

10. The method of claim 1, wherein the substrate further comprises a layer of nitride, and wherein the plasma has a nitride selectivity of at least 20:1.

11. The method of claim 1, wherein the substrate is etched in such as way as to cause the formation of a hole in the substrate.

12. The method of claim 11, wherein the use of the mixture under the etching conditions results in the deposition of a fluoropolymer on at least one surface of the hole.

13. The method of claim 11, wherein the hole has a width in at least one direction of less than 0.25 microns.

14. The method of claim 11, wherein the hole has a width in at least one direction of less than about 0.18 microns.

15. The method of claim 11, wherein the hole has a width in at least one direction of less than about 0.14 microns.

16. The method of claim 1, wherein the second gas has the formula C₂H₂F₄.

17. The method of claim 1, wherein the second gas is a tetrafluoroethane.

18. The method of claim 17, wherein the second gas is 1,1,1,2-tetrafluoroethane.

19. The method of claim 1, wherein the first gas is C₄F₆.

20. The method of claim 19, wherein the first gas is

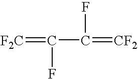

21. The method of claim 19, wherein the first gas is

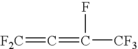

22. The method of claim 1, wherein the mixture comprises C₄F₆, C₂H₂F₄, O₂ and Ar.

23. The method of claim 1, wherein the mixture comprises C₄F₆, CH₃F, O₂ and Ar.

24. The method of claim 1, wherein the mixture comprises C₄F₆, CH₂F₂, O₂ and Ar.

25. The method of claim 1, wherein the mixture further comprises CO.

26. The method of claim 21, wherein etching is conducted within a chamber, and wherein the ratio of the flow rate of O₂ to C₂H₂F₄ into the chamber is within the range of about 2 to about 8.

27. The method of claim 25, wherein the ratio of the flow rate of O₂ to C₂H₂F₄ is within the range of about 4 to about 6.

28. The method of claim 21, wherein etching is conducted within a chamber, and wherein the ratio of the flow rate of O₂ to C₄F₆ into the chamber is within the range of about 0.5 to about 1.0.

29. The method of claim 1, wherein the mixture is varied during the etching process from a first mixture to a second mixture, and wherein the molar ratio of the second gas to the first gas is higher in the second mixture than the first mixture.

30. The method of claim 29, wherein the substrate comprises a layer of a doped oxide disposed on a layer of an undoped oxide, wherein the first and second mixtures etch doped oxide, and wherein the second mixture etches the undoped oxide at a slower rate than the rate at which the first mixture etches the doped oxide.

31. The method of claim 1, wherein the substrate is etched in a magnetically enhanced reactive ion etcher.

32. The method of claim 31, wherein the etcher is equipped with a cathode, and wherein the cathode has a temperature within the range of about 0 to about 40° C.

33. The method of claim 1, wherein the substrate is etched at a pressure within the range of about 40 to 80 mTorr.

34. The method of claim 1, wherein the substrate is etched in the presence of a magnetic field of less than about 50 Gauss.

35. The method of claim 1, wherein the substrate is etched in the presence of a magnetic field within the range of about 10 to about 40 Gauss.

36. A method for etching a substrate, comprising the steps of:
positioning in a chamber a structure comprising a first layer disposed on a substrate, the first layer being selected from the group consisting of dielectric layers and semiconductor layers;
supplying a reactive gas mixture to the chamber, the gas mixture comprising a first gas having the formula CₐF_{b} and a second gas having the formula CₓH_{y}F_{z}, wherein a/b≧⅔ and x/z≧½, and wherein a, b, x, y, and z are all greater than 0;
applying sufficient RF energy to the chamber to establish an etching plasma and an associated electric field perpendicular to the surface of the substrate;
applying a magnetic field to the chamber substantially perpendicular to the electric field and substantially parallel to the surface of the substrate; and
allowing the plasma to etch at least a portion of the first layer.

37. The method of claim 36, further comprising the steps of:
applying a masking layer to the first layer, and
forming an opening in the masking layer to expose the first layer through the opening.

38. The method of claim 36, wherein the first layer is a silicon oxide layer.

39. The method of claim 36, wherein the first layer is a silicon layer.

40. The method of claim 36, wherein the chamber is equipped with a cathode, and wherein the substrate is positioned at the cathode.

41. The method of claim 40, further comprising the step of establishing a temperature between about −40° C. and about 20° C. at the cathode prior to allowing the reactive gas mixture to etch at least a portion of the first layer.

42. The method of claim 40, further comprising the step of establishing a temperature between about 0° C. and about 20° C. at the cathode prior to allowing the reactive gas mixture to etch at least a portion of the first layer.

43. The method of claim 36, wherein the magnetic field is a DC magnetic field.

44. The method of claim 36, wherein the magnetic field is independently controllable in direction and magnitude.

45. A method for etching a substrate, comprising the steps of:
providing a substrate selected from the group consisting of semiconductor and dielectric substrates; and
etching the substrate through a magnetically enhanced reactive ion etch process, the process including the addition of a source of hydrogen radicals to a gas mixture in an amount sufficient to increase the value of at least one parameter selected from the group consisting of etch rate and selectivity of the reactive gas mixture for the substrate;
wherein the gas mixture comprises a first gas having the formula CₐF_{b} and a second gas having the formula CₓH_{y}F_{z}, and wherein a/b≧⅔ and x/z≧½, and wherein a, b, x, y, and z are all greater than 0.

46. A apparatus for etching substrates, comprising:
a chamber adapted to receive a substrate to be etched; and
at least one reservoir in open communication with said chamber, said at least one reservoir adapted to supply a gas mixture to the chamber, said gas mixture comprising a first gas having the formula Cab and a second gas having the formula CₓH_{y}F_{z}, wherein a/b≧⅔ and x/z≧½, and wherein a, b, x, y, and z are all greater than 0.

47. The apparatus of claim 46, wherein said gas mixture further comprises oxygen.

48. The apparatus of claim 46, wherein the second gas has the formula C₂H₂F₄.

49. The apparatus of claim 46, wherein the second gas is a tetrafluoroethane.

50. The apparatus of claim 46, wherein the second gas is 1,1,1,2-tetrafluoroethane.

51. The apparatus of claim 46, wherein the first gas is C₄F₆.

52. The apparatus of claim 46, wherein the first gas is

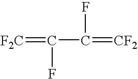

53. The apparatus of claim 46, wherein the first gas is

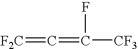

54. The apparatus of claim 46, wherein the mixture comprises C₄F₆, C₂H₂F₄, O₂ and Ar.

55. The apparatus of claim 46, wherein the mixture comprises C₄F₆, CH₃F, O₂ and Ar.

56. The apparatus of claim 46, wherein the mixture comprises C₄F₆, CH₂F₂, O₂ and Ar.

57. The apparatus of claim 46, wherein the mixture farther comprises CO.

58. The apparatus of claim 54, wherein the ratio of the flow rate of O₂ to C₂H₂F₄ into the chamber is within the range of about 2 to about 8.

59. The apparatus of claim 54, wherein the ratio of the flow rate of O₂ to C₂H₂F₄ is within the range of about 4 to about 6.

60. The apparatus of claim 54, wherein the ratio of the flow rate of O₂ to C₄F₆ into the chamber is within the range of about 0.5 to about 1.0.

61. The apparatus of claim 46, wherein the mixture is varied during the etching process from a first mixture to a second mixture, and wherein the molar ratio of the second gas to the first gas is higher in the second mixture than the first mixture.

62. The apparatus of claim 46, wherein said at least one reservoir comprises a first, second, third, and fourth reservoir, wherein said first reservoir contains C₄F₆, wherein said second reservoir contains C₂H₂F₄, wherein said third reservoir contains O₂, and wherein said fourth reservoir contains Ar.

63. The apparatus of claim 62, wherein each of said first, second, third and fourth reservoirs is equipped with a control valve for controlling the flow rate of gas from the reservoir.

64. The apparatus of claim 46, further equipped with a device for analyzing the composition of the atmosphere within the chamber.

65. The apparatus of claim 64, wherein said at least one reservoir comprises at least a first and second reservoir, and wherein the apparatus is adapted to adjust the flow of gas from said first and second reservoirs in response to the composition of the atmosphere within the chamber.

66. The apparatus of claim 64, wherein said first reservoir contains C₄F₆, wherein said second reservoir contains C₂H₂F₄, wherein the ratio of the rate of gas flow from the first reservoir to the rate of gas flow from the second reservoir is r, wherein the concentration of boron in the chamber is b, and wherein, for constants m,n>0, r<m when b<n and r≧n when b≧n.

67. A method for etching a substrate, comprising the steps of:
providing a substrate selected from the group consisting of semiconductor and dielectric substrates;
etching the substrate through the use of a plasma based on a gaseous mixture comprising C₄F₆, O₂, and Ar, thereby forming a modified substrate; and
further etching the modified substrate through the use of a plasma based on a gaseous mixture comprising C₄F₆, O₂, Ar, and C₂H₂F₄.

68. A method for etching a substrate, comprising the steps of:
providing a substrate comprising (a) a first layer comprising a doped oxide, and (b) a second layer, comprising an undoped oxide;
etching the substrate through the use of a plasma based on a first gaseous mixture comprising C₄F₆, O₂ and Ar so as to form a depression that extends at least partially through the second layer, but does not extend substantially into the first layer, thereby forming a modified substrate; and
etching the modified substrate through the use of a plasma based on a second gaseous mixture comprising C₄F₆, O₂, C₂H₂F₄, and Ar so as to extend the depression substantially into the first layer.

69. The method of claim 68, wherein the first layer comprises boron phosphorosilicate glass.

70. The method of claim 68, wherein the second layer comprises tetraethylorthosilicate.

71. The method of claim 68, wherein said first and second gaseous mixtures are distinct.

72. The method of claim 68, wherein the substrate is etched with the first gaseous mixture so as to form a depression that extends only partially through the second layer.

73. The method of claim 68, wherein the substrate is further provided with a third layer comprising a photo resist.

74. The method of claim 68, wherein the second layer is contiguous to the first layer.

75. An article, comprising:
a substrate;
first and second gate structures disposed on said substrate, said first and second gate structures being separated by a gap of less than about 0.25 microns;
a layer of silicon nitride disposed over said gate structures and said gap;
a layer of doped oxide disposed over said layer of silicon nitride; and
a layer of undoped oxide disposed over said layer of doped oxide.

76. The article of claim 75, wherein said doped oxide comprises boron phosphorosilicate glass.

77. The article of claim 75, wherein said undoped oxide comprises tetraethylorthosilicate.

78. The article of claim 75, further comprising an antireflective layer disposed over said layer of undoped oxide.

79. The article of claim 78, further comprising a layer of photo resist disposed over said antireflective layer.

80. The article of claim 78, wherein said layer of photo resist contains a second gap which overlaps said first gap, and wherein the minimum width of the second gap is greater than the maximum width of the first gap.
